(19) United States
(12) Patent Application Publication
(10) Pub. No.: US 2018/0294395 A1
(43) Pub. Date: Oct. 11, 2018

(54) Doped lanthanum chromate thin-film thermocouple and preparation method thereof

(71) Applicant: XI'AN JIAOTONG UNIVERSITY, Xi'an, Shaanxi (CN)

(72) Inventors: Peng Shi, Xi'an, Shaanxi (CN); Wei Ren, Xi'an, Shaanxi (CN); Dan Liu, Xi'an, Shaanxi (CN); Ming Liu, Xi'an, Shaanxi (CN); Bian Tian, Xi'an, Shaanxi (CN); Zhuangde Jiang, Xi'an, Shaanxi (CN)

(21) Appl. No.: 15/762,819

(22) PCT Filed: Oct. 18, 2016
(86) PCT No.: PCT/CN2016/102463

§ 371 Date: Mar. 23, 2018

(30) Foreign Application Priority Data
Apr. 27, 2016 (CN) 201610272878.X

(51) Int. Cl. H01L 35/14; C04B 35/50; G01K 7/02; H01L 35/32; H01L 35/34

(52) U.S. Cl. CPC H01L 35/14; C04B 35/50; G01K 7/02; H01L 35/32; C04B 2235/3227; C04B 2235/3213; C04B 2235/3241; C04B 2235/3208; C04B 2235/3279; H01L 35/34

(57) ABSTRACT

A doped lanthanum chromate thin-film thermocouple includes two thermodes (1, 2) arranged on a ceramic substrate (3), wherein: the two thermodes (1, 2) are overlapped with each other; both of the thermodes (1, 2) are made of doped lanthanum chromate thin film; at least one doping element selected from a group consisting of Mg, Ca, Sr, Ba, Co, Cu, Sm, Fe, Ni and V is doped in each lanthanum chromate thin film; and the lanthanum chromate thin films adopted by the two thermodes (1, 2) are doped with in different doping elements or with a same doping element of different contents. A method for preparing the doped lanthanum chromate thin-film thermocouple is also provided.

### CROSS REFERENCE OF RELATED APPLICATION

This is a U.S. National Stage under 35 U.S.C 371 of the International Application PCT/CN2016/102463, filed Oct. 18, 2016, which claims priority under 35 U.S.C. 119(a-d) to CN 201610272878.X, filed Apr. 27, 2016.

### BACKGROUND OF THE PRESENT INVENTION

### Field of Invention

The present invention relates to fields of sensor preparation technology and high-temperature measurement technology, and more particularly to a doped lanthanum chromate thin-film thermocouple and a preparation method thereof.

### Description of Related Arts

In the aero-engine design and verification experiment, in order to verify the combustion efficiency of the engine and the design of the cooling system, it is required to accurately measure the temperatures at the turbine blade surface of the engine, the inner wall of the combustor, etc. Compared with the conventional wire and block thermocouples, the high-temperature ceramic thin-film thermocouple has the advantages of small thermal capacity, small volume and fast response speed and is able to capture the transient temperature change; and meanwhile, the thin-film thermocouple can be directly deposited on the surface of the measured component without damaging the structure of the measured component and has a little influence on the working environment of the measured component. Thus, the thin-film thermocouple is more applicable to the surface transient temperature measurement. The distribution condition of the surface temperature of the components at the hot end can be accurately known through the thin-film thermocouple, so that the heat transmission and cooling schematic designs can be optimized, thereby guaranteeing the engine at the best working condition, increasing the efficiency of the engine, and providing the reliable basis for the design of the new-generation fighter plane and airliner.

Conventionally, the research of the NiCr/NiSi thin-film thermocouple is relatively mature, while the NiCr/NiSi thin-film thermocouple has the low temperature measurement range and is merely applicable to the medium-low temperature measurement occasion. In the high-temperature measurement field, the noble metal such as platinum and rhodium generally serves as the thin-film material, but has the problems of high cost, large error and easy oxidation at the severe environment. Thus, it is urgent to develop a ceramic thin-film thermocouple having the high-temperature resistance and the stable performances. In the existing research, the thin-film ITO (Indium-Tin Oxide) and In₂O₃ materials are expected to be the first-choice material of the high-temperature measurement. However, it is found by the further research that the ITO thin-film thermocouple has the severe thermal volatilization at the high-temperature area of large than 1000° C. and therefore causes the unstable high-temperature measurement and the limited highest temperature, which seriously limits the application of the ITO thin film in the high-temperature measurement fields such as the high-temperature hot runner.

LaCrO₃ as a typical p-type oxide conductive material has advantages of high melting point (2400° C.), relatively good conductivity, and stable physical and chemical properties in the oxidizing and reducing atmosphere. Through doping with elements of different valence states, the conductivity and the high-temperature stability of LaCrO₃ will be increased. Conventionally, LaCrO₃ has been widely applied in the anode and connector material of the SOFC (Solid Oxide Fuel Cell). If two doped lanthanum chromate materials having different conduction characteristics are rationally combined, it is possible to become a new high-temperature thin-film thermocouple.

### SUMMARY OF THE PRESENT INVENTION

An object of the present invention is to provide a doped lanthanum chromate thin-film thermocouple can be applied in high-temperature measurement under an extreme environment and a preparation method thereof, so as to solve problems in prior art.

In order to accomplish the above object, following technical solutions are provided by the present invention.

A doped lanthanum chromate thin-film thermocouple comprises two thermodes arranged on a ceramic substrate, wherein: the two thermodes are overlapped with each other; both of the thermodes are made of doped lanthanum chromate thin film; at least one doping element selected from a group consisting of Mg, Ca, Sr, Ba, Co, Cu, Sm, Fe, Ni and V is doped in each lanthanum chromate thin film; and, the lanthanum chromate thin films adopted by the two thermodes are doped with different doping elements or with a same doping element of different contents.

A content of the doping element in each lanthanum chromate thin film is 0-40%.

The two thermodes are arranged mirror-symmetrically along a center line of the ceramic substrate; and the two thermodes are overlapped to form a U-shaped structure or a V-shaped structure.

Each thermode has a length of 8-30 cm, a width of 0.2-1.55 cm and a thickness of 0.3-50 μm; and an overlapping area of the two thermodes has a length of 0.5-3 cm.

The ceramic substrate is made of high-temperature resistant ceramic, such as aluminum oxide ceramic, mullite ceramic or SiC ceramic.

A method for preparing a doped lanthanum chromate thin-film thermocouple comprises steps of: selecting two thermode materials which are doped with different doping elements or with a same doping element of different contents; through magnetron sputtering, screen printing, pulsed laser deposition or a chemical solution method, depositing the thermode materials into thin-film thermodes on a ceramic substrate; and through high-temperature heat treatment, obtaining the doped lanthanum chromate thin-film thermocouple.

The high-temperature heat treatment is processed at a temperature of 600-1200° C.

Compared with the prior art, according to the present invention, the excellent characteristic of high Seebeck coefficient showed by the lanthanum chromate thin-film material after doping and modifying is utilized, and two thin films with different conduction characteristics are adopted to form the thin-film thermocouple which is applicable to the temperature measurement in a high-temperature oxidizing atmosphere and is able to stably work under a high temperature of 1200-1600° C. for a long term. The thermocouple provided by the present invention has a relatively high output voltage and therefore has a relatively high sensitivity during calibration. Compared with the conventional K-type thermocouple, through adopting the ceramic thermocouple material, the thermocouple provided by the present invention has the wider temperature measurement range and is able to adapt to the oxidation and acid-base environment. Compared with adopting the high-temperature resistant thermocouple material of other types, such as platinum and rhodium, the thermocouple provided by the present invention has the lower cost in the same temperature measurement range. Compared with the conventional ceramic thin-film thermocouple, such as the ITO (Indium-Tin Oxide) ceramic thin-film thermocouple, the thermocouple provided by the present invention has the higher using temperature and longer high-temperature using time, and is applicable to the extreme environment temperature measurement in the fields of aerospace and so on.

Compared with the prior art, according to the method provided by the present invention, two thermode materials with the different doping elements or with the same doping element of different contents are selected; through magnetron sputtering, screen printing, pulsed laser deposition or the chemical solution method, the doped lanthanum chromate oxide thin films are deposited on the high-temperature ceramic substrate; and then through the high-temperature heat treatment, the thin-film thermocouple which is able to stably output the signal at the high temperature is finally obtained. The obtained thermocouple is applicable to the high-temperature measurement at the extreme environment, has an easy and reliable preparation process, and is able to stably work under the high temperature of 1200-1600° C. for a long term. Compared with the convention K-type thermocouple, the thermocouple provided by the present invention has the wider temperature measurement range and is able to adapt to the oxidation and acid-base environment. Compared with adopting the high-temperature resistant thermocouple material of other types, such as platinum and rhodium, the thermocouple provided by the present invention has the lower cost in the same temperature measurement range.

Compared with the conventional ceramic thin-film thermocouple, such as the ITO ceramic thin-film thermocouple, the thermocouple provided by the present invention has the higher using temperature and longer high-temperature using time, and is applicable to the extreme environment temperature measurement in the fields of aerospace and so on.

### BRIEF DESCRIPTION OF THE DRAWINGS

FIG. 1 is a structural sketch view of a U-shaped La_{0.8}Sr_{0.2}CrO₃—LaCrO₃ thin-film thermocouple according to a first preferred embodiment of the present invention. In FIG. 1, 1: La_{0.8}Sr_{0.2}CrO₃ thermode; 2: LaCrO₃ thermode; 3: aluminum oxide ceramic substrate; and 4: electrode.

FIG. 2 is a sketch view of XRD (X-Ray Diffraction) results of La_{0.8}Sr_{0.2}CrO₃ powders and LaCrO₃ powders for screen printing according to the first preferred embodiment of the present invention.

FIG. 3a is an SEM (Scanning Electron Microscope) photo of the La_{0.8}Sr_{0.2}CrO₃ powders for the screen printing according to the first preferred embodiment of the present invention.

FIG. 3b is an SEM photo of the LaCrO₃ powders according to the first preferred embodiment of the present invention.

FIG. 4 is a sketch view of time-temperature-voltage curves of the La_{0.8}Sr_{0.2}CrO₃—LaCrO₃ thin-film thermocouple prepared through the screen printing according to the first preferred embodiment of the present invention.

### DETAILED DESCRIPTION OF THE PREFERRED EMBODIMENT

The present invention is further illustrated with preferred embodiments as follows.

For a thermocouple provided by the present invention, two different doped lanthanum chromate thin films are selected as two thermode materials of the thin-film thermocouple, wherein: the materials can be doped with a same doping element of different contents and can also be single-doped or co-doped with different doping elements; and the doping elements mainly comprise Mg, Ca, Sr, Ba, Co, Cu, Sm, Fe, Ni and V. Then, according to a designed doping composition, through magnetron sputtering, screen printing or a chemical spin-coating process, the oxide thin-film thermocouple applicable to high-temperature measurement is deposited on a high-temperature ceramic substrate, and a device structure having structural features of the thermocouple is formed through a patterning technology, wherein: a pattern of the thermocouple can be V-shaped or U-shaped; a hot end overlapping area of the thin-film thermocouple is formed by a local overlapping area between two thermodes; the overlapping area has a length between 0.5-3 cm; each thermode of the thin-film thermocouple has a thickness in a range of 0.3-50 μm, a length between 8-30 cm and a width of 0.2-1.55 cm. Finally, the prepared thin-film thermocouple is processed with a high-temperature heat treatment at a temperature of 600-1200° C. for 1-3 hours, so as to increase density of the thin films; and the oxide thin-film thermocouple able to stably work in a high-temperature oxidizing atmosphere is finally obtained.

According to a stoichiometric method, chemical formulas formed after doping with various elements are described as follows.

When Cr is partly replaced by Mg, the chemical formula is LaCr₁₋ₓMgₓO₃.

When La is partly replaced by Ca, the chemical formula is La₁₋ₓCaₓCrO₃.

When La is partly replaced by Sr, the chemical formula is La₁₋ₓSrₓCrO₃.

When La is partly replaced by Ba, the chemical formula is La₁₋ₓBaₓCrO₃.

When Cr is partly replaced by Fe, the chemical formula is LaCr₁₋ₓFeₓO₃.

When La is partly replaced by Sm, the chemical formula is La₁₋ₓSmₓCrO₃.

When Cr is partly replaced by Cu, the chemical formula is LaCr₁₋ₓCuₓO₃.

When Cr is partly replaced by Co, the chemical formula is LaCr₁₋ₓCoₓO₃.

When Cr is partly replaced by Ni, the chemical formula is LaCr₁₋ₓNiₓO₃.

Principles of the present invention are described as follows. Seebeck effect, which is also called first thermoelectric effect, means a thermoelectric phenomenon of a voltage difference between two materials caused by a temperature difference between two different electric conductors or semiconductors. Seebeck coefficient S represents a temperature-based material characteristic. If a Seebeck coefficient S(T) of one material is known, the voltage difference between two thermodes can be known from formula transformation, so that the temperature difference between a cold end and a hot end is indirectly obtained.

$$Δ V = {\int }_{{T}_{1}}^{{T}_{2}} SdT$$

From the above formula, it can be known that: with a temperature increase, energy in a Fermi distribution function increases rapidly, so that an electron mean energy of a heated end is relatively high. Correspondingly, electrons at the heated end are continuously diverged to the cold end, until a voltage difference avoiding a further divergence is formed. Through mathematical derivation, it can be further known that the expression of the Seebeck coefficient is

$$S \approx \frac{{π}^{2} {k}^{2} T}{2 {eE}_{F 0}} ,$$

wherein: E_{FO} is Fermi energy when 0 K. From the above formula, it can be known that the Seebeck coefficient is related to the own Fermi energy of the material, and is also related to an actual absolute temperature value. That is to say, for two thermode materials, if the temperatures of the hot and cold ends are determined, the temperature difference and the voltage difference are fixed. The above-mentioned is an essential basic requirement on the high-temperature thermocouple. Similarly, if the Seebeck coefficients of two thermode materials are inconsistent, a sensible thermoelectric force difference between the cold ends of the two thermodes will be formed.

LaCrO₃ as a typical p-type oxide conductive material has advantages of high melting point (2400° C.), relatively good conductivity, and stable physical and chemical properties in the oxidizing and reducing atmosphere. Through doping with different elements, the conductivity and the high-temperature stability of LaCrO₃ will be increased. Because the scattering mechanism of the carriers changes after doping, the electrical properties are changed, so that the Fermi energy level and the intrinsic Seebeck coefficient of the material are also changed. Therefore, two different doped lanthanum chromate thin films are selected as two thermode materials of the thin-film thermocouple, so as to form the thin-film thermocouple which can stably work at the high temperature.

### First Preferred Embodiment

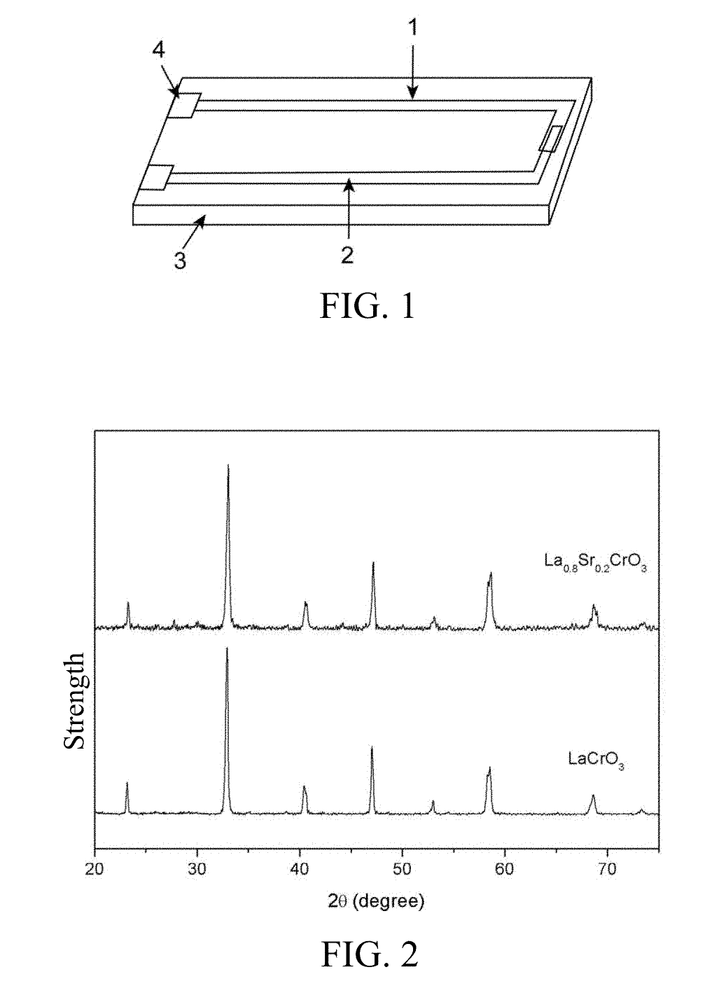

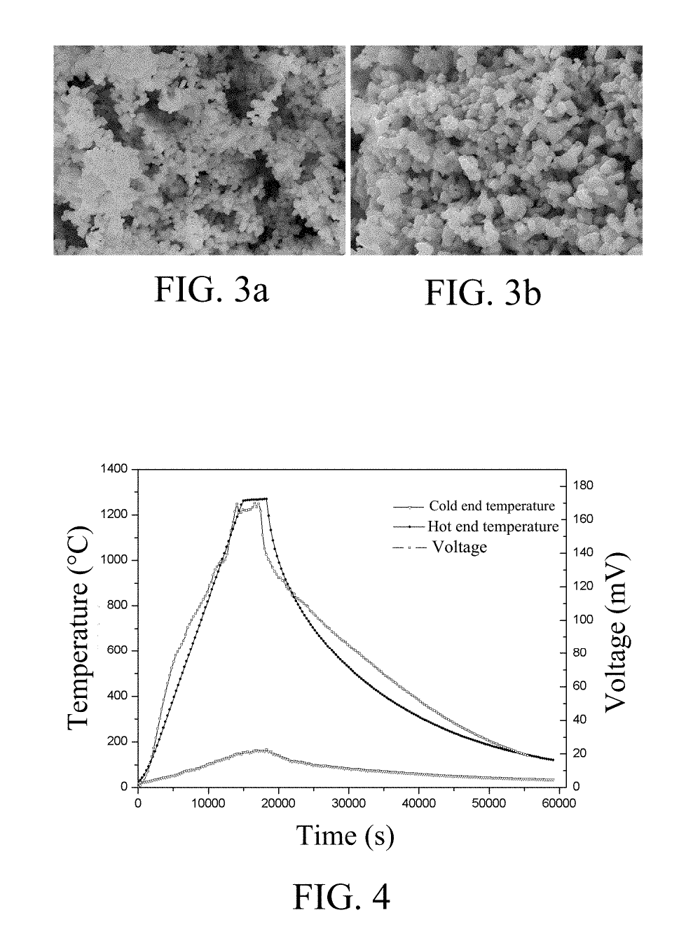

La_{0.8}Sr_{0.2}CrO₃ powders and LaCrO₃ powders are selected as electrode materials of the thermocouple, and through the screen printing, thin-film electrodes are deposited on an aluminum oxide ceramic substrate 3 which has a thickness of 1 mm, wherein: ceramic slurry for the screen printing is obtained through adding ceramic powders with a ratio of 1:1 into an organic solvent and then strongly stirring and mixing; the ceramic powders comprises the La_{0.8}Sr_{0.2}CrO₃ powders and the LaCrO₃ powders; both of the La_{0.8}Sr_{0.2}CrO₃ powders and the LaCrO₃ powders have a particle size of about 200 nm; and the organic solvent is a mixed solution of ethylene cellulose and terpilenol with a ratio of 1:2. For well patterning, a U-shaped mask plate with a thermode length of 12 cm and a thermode width of 0.8 cm is selected for preparation of the screen printing of the thin-film electrodes, wherein the mask plate has a mesh number of 200. An LaCrO₃ thin film is firstly printed on the substrate, and then an La_{0.8}Sr_{0.2}CrO₃ thin film is printed. After finishing deposition of two thin-film materials, the thin-film sample is processed with heat treatment in a muffle furnace at 700° C. for 1 hour with a temperature increase speed kept at 5° C./min, and finally a U-shaped La_{0.8}Sr_{0.2}CrO₃—LaCrO₃ thin-film thermocouple with a thin film thickness of 50 μm is prepared. FIG. 1 is a structural sketch view of a U-shaped La_{0.8}Sr_{0.2}CrO₃—LaCrO₃ thin-film thermocouple, wherein: the La_{0.8}Sr_{0.2}CrO₃ thermode 1 is overlapped with the LaCrO₃ thermode 2 to form the U-shaped thermocouple, and two ends of the thermocouple are connected with electrodes 4. FIG. 2 is a sketch view of XRD (X-Ray Diffraction) results of the La_{0.8}Sr_{0.2}CrO₃ powders and the LaCrO₃ powders for the screen printing. FIG. 3 is an SEM (Scanning Electron Microscope) photo of the La_{0.8}Sr_{0.2}CrO₃ powders and the LaCrO₃ powders for the screen printing. FIG. 4 is a sketch view of time-temperature-voltage curves of the thin-film thermocouple prepared through the screen printing, indicating that the oxide thin-film thermocouple is able to stably work at a temperature of 1270° C.

### Second Preferred Embodiment

La_{0.9}Sr_{0.1}CrO₃ powders and LaCrO₃ powders are selected as electrode materials of the thermocouple, and through the screen printing, thin-film electrodes are deposited on an aluminum oxide ceramic substrate which has a thickness of 3 mm, wherein: ceramic slurry for the screen printing is obtained through adding ceramic powders with a ratio of 2:3 into an organic solvent and then strongly stirring and mixing; the ceramic powders comprises the La_{0.9}Sr_{0.1}CrO₃ powers and the LaCrO₃ powders; both of the La_{0.9}Sr_{0.1}CrO₃ powers and the LaCrO₃ powders have a particle size of about 100 nm; and the organic solvent is a mixed solution of ethylene cellulose and terpilenol with a ratio of 1:2. For well patterning, a U-shaped mask plate with a thermode length of 25 cm and a thermode width of 1.5 cm is selected for preparation of the screen printing of the thin-film electrodes. A LaCrO₃ thin film is first printed on the substrate, and then a La_{0.9}Sr_{0.1}CrO₃ thin film is printed. After finishing deposition of two thin-film materials, the thin-film sample is processed with heat treatment in a muffle furnace at 1200° C. for 5 hours with a temperature increase speed kept at 3° C./min, and finally a U-shaped La_{0.9}Sr_{0.1}CrO₃—LaCrO₃ thin-film thermocouple with a thin film thickness of 40 μm is prepared.

### Third Preferred Embodiment

La_{0.8}Sr_{0.2}CrO₃ powders and La_{0.9}Sr_{0.1}CrO₃ powders are selected as electrode materials of the thermocouple, and through the screen printing, thin-film electrodes are deposited on an aluminum oxide ceramic substrate which has a thickness of 10 mm, wherein: ceramic slurry for the screen printing is obtained through adding ceramic powders with a ratio of 1:1 into an organic solvent and then strongly stirring and mixing; the ceramic powders comprises the La_{0.8}Sr_{0.2}CrO₃ powders and the La_{0.9}Sr_{0.1}CrO₃ powders; both of the La_{0.8}Sr_{0.2}CrO₃ powders and the La_{0.9}Sr_{0.1}CrO₃ powders have a particle size of about 200 nm; and the organic solvent is a mixed solution of ethylene cellulose and terpilenol with a ratio of 1:2. For well patterning, a U-shaped mask plate with a thermode length of 20 cm and a thermode width of 1.0 cm is selected for preparation of the screen printing of the thin-film electrodes, wherein the mask plate has a mesh number of 200. An La_{0.9}Sr_{0.1}CrO₃ thin film is firstly printed on the substrate, and then an La_{0.8}Sr_{0.2}CrO₃ thin film is printed. After finishing deposition of two thin-film materials, the thin-film sample is processed with heat treatment in a muffle furnace at 700° C. for 3 hours with a temperature increase speed kept at 5° C./min, and finally a U-shaped La_{0.8}Sr_{0.2}CrO₃—La_{0.9}Sr_{0.1}CrO₃ thin-film thermocouple with a thin film thickness of 50 μm is prepared.

### Fourth Preferred Embodiment

Two Ca-doped lanthanum chromate thin films with different doping amounts are selected as two thermode materials of the thin-film thermocouple, wherein: doping concentrations are respectively 10% and 30%; and the two materials are respectively denoted as LCC1 and LCC3. Through magnetron sputtering technology, the thin films are deposited on a 99 aluminum oxide substrate which has a thickness of 2 mm. Firstly oxide ceramic target materials having the same composition as the designed composition are prepared for the sputtering of the thin films. Through adjusting a sputtering pressure (5 Pa), an oxygen-argon ratio (1:6) and a sputtering power (120 W), a U-shaped LCC1-LCC3 thin-film thermocouple with a thickness of 5 μm, a thermode length of 20 cm and a thermode width of 0.6 cm is obtained after sputtering for 8 hours, wherein an overlapping area between hot ends of two thermodes has a length of 1.5 cm. Finally, the prepared thin-film thermocouple is processed with heat treatment at 800° C. for 3 hours, and the oxide thin-film thermocouple able to stably work in the high-temperature oxidizing atmosphere is obtained.

### Fifth Preferred Embodiment

Sr-doped lanthanum chromate thin film and Ca-doped lanthanum chromate thin film are selected as two thermode materials of the thin-film thermocouple, wherein: doping concentrations are respectively 40% and 10%; and the two materials are respectively denoted as LSC4 and LCC1. Through a chemical solution deposition technology, the thin films are deposited and prepared. Firstly Sr-doped and Ca-doped strontium titanate precursor solutions (with a concentration of 0.4 mol/L) conforming to stoichiometric ratios are respectively prepared, and then the thin films are prepared through a spin-coating process. An LSC4 thin film is firstly prepared through spin-coating, and then an LCC1 thin film is prepared. A rotation speed of spin-coating of the thin films is preset to be 2500 rpm; a wet film obtained after every time of spin-coating is firstly dried at 400° C. for 5 minutes and then processed with heat treatment at 650° C. for 10 minutes, and then spin-coating deposition is repeated; for each thermode, the spin-coating deposition is repeated for 15 times, and a U-shaped LSC4-LCC1 thin-film thermocouple with a thickness of 1 μm, a thermode length of 20 cm and a thermode width of 0.3 cm is obtained, wherein an overlapping area between hot ends of two thermodes has a length of 1.2 cm. Finally, the prepared thin-film thermocouple is processed with the heat treatment at 900° C. for 4 hours, and the oxide thin-film thermocouple able to stably work in the high-temperature oxidizing atmosphere is obtained.

### Sixth Preferred Embodiment

Sr-doped lanthanum chromate thin films with different doping amounts and Ni-doped lanthanum chromate thin films with different doping amounts are selected as two thermode materials of the thin-film thermocouple, wherein: doping concentrations of the Sr-doped lanthanum chromate thin films are respectively 10% and 20%; and doping concentration of the Ni-doped lanthanum chromate thin films are respectively 10% and 40%; and the two materials are respectively denoted as LSCN2 and LSCN4. Through a magnetron sputtering technology, the thin films are deposited on a 99 aluminum oxide substrate which has a thickness of 2 mm. Firstly, oxide ceramic target materials having a composition same as the designed composition are prepared for sputtering of the thin films. Through adjusting a sputtering pressure (5 Pa), an oxygen-argon ratio (1:6) and a sputtering power (120 W) of the sputtering process, a U-shaped LSCN2-LSCN4 thin-film thermocouple with a thickness of 5 μm, a thermode length of 20 cm and a thermode width of 0.6 cm is obtained after sputtering for 8 hours, wherein an overlapping area between hot ends of two thermodes has a length of 1.5 cm. Finally, the prepared thin-film thermocouple is processed with heat treatment at 800° C. for 3 hours, and the oxide thin-film thermocouple able to stably work in the high-temperature oxidizing atmosphere is obtained.

1. A doped lanthanum chromate thin-film thermocouple, comprising two thermodes arranged on a ceramic substrate, wherein: the two thermodes are overlapped with each other; both of the thermodes are made of doped lanthanum chromate thin film; at least one doping element selected from a group consisting of Mg, Ca, Sr, Ba, Co, Cu, Sm, Fe, Ni and V is doped in each lanthanum chromate thin film; and, the lanthanum chromate thin films adopted by the two thermodes are doped with different doping elements or with a same doping element of different contents.

2. The doped lanthanum chromate thin-film thermocouple, as recited in claim 1, wherein a content of the doping element in each lanthanum chromate thin film is 0-40%.

3. The doped lanthanum chromate thin-film thermocouple, as recited in claim 1, wherein: the two thermodes are arranged mirror-symmetrically along a center line of the ceramic substrate; and the two thermodes are overlapped to form a U-shaped structure or a V-shaped structure.

4. The doped lanthanum chromate thin-film thermocouple, as recited in claim 3, wherein: each thermode has a length of 8-30 cm, a width of 0.2-1.55 cm and a thickness of 0.3-50 μm; and an overlapping area of the two thermodes has a length of 0.5-3 cm.

5. The doped lanthanum chromate thin-film thermocouple, as recited in claim 1, wherein the ceramic substrate is made of high-temperature resistant ceramic, such as aluminum oxide ceramic, mullite ceramic or SiC ceramic.

6-7. (canceled)

8. A method for preparing a doped lanthanum chromate thin-film thermocouple as recited in claim 1, comprising steps of: selecting two thermode materials which are doped with different doping elements or with a same doping element of different contents; through magnetron sputtering, silk-screen printing, pulsed laser deposition or a chemical solution method, depositing the thermode materials into thin-film thermodes on a ceramic substrate; and through high-temperature heat treatment, obtaining the doped lanthanum chromate thin-film thermocouple.

9. A method for preparing a doped lanthanum chromate thin-film thermocouple as recited in claim 2, comprising steps of: selecting two thermode materials which are doped with different doping elements or with a same doping element of different contents; through magnetron sputtering, silk-screen printing, pulsed laser deposition or a chemical solution method, depositing the thermode materials into thin-film thermodes on a ceramic substrate; and through high-temperature heat treatment, obtaining the doped lanthanum chromate thin-film thermocouple.

10. A method for preparing a doped lanthanum chromate thin-film thermocouple as recited in claim 3, comprising steps of: selecting two thermode materials which are doped with different doping elements or with a same doping element of different contents; through magnetron sputtering, silk-screen printing, pulsed laser deposition or a chemical solution method, depositing the thermode materials into thin-film thermodes on a ceramic substrate; and through high-temperature heat treatment, obtaining the doped lanthanum chromate thin-film thermocouple.

11. A method for preparing a doped lanthanum chromate thin-film thermocouple as recited in claim 4, comprising steps of: selecting two thermode materials which are doped with different doping elements or with a same doping element of different contents; through magnetron sputtering, silk-screen printing, pulsed laser deposition or a chemical solution method, depositing the thermode materials into thin-film thermodes on a ceramic substrate; and through high-temperature heat treatment, obtaining the doped lanthanum chromate thin-film thermocouple.

12. A method for preparing a doped lanthanum chromate thin-film thermocouple as recited in claim 5, comprising steps of: selecting two thermode materials which are doped with different doping elements or with a same doping element of different contents; through magnetron sputtering, silk-screen printing, pulsed laser deposition or a chemical solution method, depositing the thermode materials into thin-film thermodes on a ceramic substrate; and through high-temperature heat treatment, obtaining the doped lanthanum chromate thin-film thermocouple.

13. The method for preparing the doped lanthanum chromate thin-film thermocouple, as recited in claim 8, wherein the high-temperature heat treatment is processed at a temperature of 600-1200° C.

14. The method for preparing the doped lanthanum chromate thin-film thermocouple, as recited in claim 9, wherein the high-temperature heat treatment is processed at a temperature of 600-1200° C.

15. The method for preparing the doped lanthanum chromate thin-film thermocouple, as recited in claim 10, wherein the high-temperature heat treatment is processed at a temperature of 600-1200° C.

16. The method for preparing the doped lanthanum chromate thin-film thermocouple, as recited in claim 11, wherein the high-temperature heat treatment is processed at a temperature of 600-1200° C.

17. The method for preparing the doped lanthanum chromate thin-film thermocouple, as recited in claim 12, wherein the high-temperature heat treatment is processed at a temperature of 600-1200° C.
